(19) United States
(12) Patent Application Publication
(10) Pub. No.: US 2025/0024665 A1
(43) Pub. Date: Jan. 16, 2025

(54) SEMICONDUCTOR MEMORY DEVICE

(71) Applicant: Samsung Electronics Co., Ltd., Suwon-si (KR)

(72) Inventors: Yong Jin LEE, Suwon-si (KR); Sung Won YOO, Suwon-si (KR); Won Sok LEE, Suwon-si (KR); Min Hee CHO, Suwon-si (KR); Si Yeon CHO, Suwon-si (KR)

(73) Assignee: Samsung Electronics Co., Ltd., Suwon-si (KR)

(21) Appl. No.: 18/584,646

(22) Filed: Feb. 22, 2024

(30) Foreign Application Priority Data
Jul. 11, 2023 (KR) 10-2023-0089706

(51) Int. Cl. H10B 12/00

(52) U.S. Cl. CPC H10B 12/488; H10B 12/05; H10B 12/482

(57) ABSTRACT

The semiconductor memory device including a bit line in a first direction on a substrate, a channel structure on the bit line, and including a first vertical part in a second direction, and a second vertical part apart from the first vertical part in the first direction and in the second direction, a back-gate electrode on the bit line on a side of the channel structure and in the second direction, a back-gate insulating film between the back-gate electrode and the channel structure, a back-gate capping film on the back-gate electrode and the back-gate insulating film, a first and second word lines between the first and the second vertical parts and in the second direction, the second word line spaced apart from the first word line in the first direction and first and second capacitors connected to the first and second vertical parts, on the first and second vertical parts.

### CROSS-REFERENCE TO RELATED APPLICATION

This application claims priority from Korean Patent Application No. 10-2023-0089706 filed on Jul. 11, 2023 in the Korean Intellectual Property Office, and all the benefits accruing therefrom under 35 U.S.C. 119, the contents of which in its entirety are herein incorporated by reference.

### BACKGROUND

### 1. Field of the Invention

The present inventions relate to semiconductor memory devices, and more particularly to semiconductor memory devices including a vertical channel transistor (VCT).

### 2. Description of the Related Art

There is a need to increase the degree of integration of a semiconductor memory device to satisfy excellent performance and low price required by consumers. In the case of the semiconductor memory device, because the degree of integration is an important factor in determining the price of a product, an increased degree of integration is particularly required.

In the case of a two-dimensional or planar semiconductor memory device, the degree of integration is mainly determined by an area occupied by unit memory cells, and is therefore greatly affected by the level of fine pattern forming technology. However, since ultra-expensive apparatuses are required to miniaturize the pattern, the degree of integration of the two-dimensional semiconductor memory device is increasing, but is still limited. Accordingly, semiconductor memory devices that include a vertical channel transistor having a channel extending in a vertical direction are being proposed.

### SUMMARY

Aspects of the present inventions provide semiconductor memory devices having improved degree of integration and electrical characteristics.

However, aspects of the present inventions are not restricted to the one set forth herein. The above and other aspects of the present inventions will become more apparent to one of ordinary skill in the art to which the present inventions pertains by referencing the detailed description of the present inventions given below.

According to some aspects of the present disclosure, there is provided a semiconductor memory device including a bit line extending in a first direction on a substrate, a channel structure on the bit line, the channel structure including a first vertical part extending in a second direction, and a second vertical part spaced apart from the first vertical part in the first direction and extending in the second direction, a back gate electrode on the bit line on at least one side of the channel structure and extending in the second direction, a back gate insulating film between the back gate electrode and the channel structure, a back gate capping film on the back gate electrode and the back gate insulating film, a first word line between the first vertical part and the second vertical part and extending in the second direction, a second word line \] between the first vertical part and the second vertical part, extending in the second direction, and spaced apart from the first word line in the first direction and a first capacitor and a second capacitor connected to the first vertical part and the second vertical part, on the first vertical part and the second vertical part.

According to some aspects of the present disclosure, there is provided a semiconductor memory device including a bit line extending in a first direction on a substrate, a back gate structure defining a channel trench exposing the bit line and extending in a second direction intersecting the first direction, on the substrate, an etching stop film between the back gate structure and the bit line, a channel structure extending along a lower surface and side faces of the channel trench, and including a first channel pattern, and a second channel pattern spaced apart from the first channel pattern in the first direction, a first word line and a second word line spaced apart from each other in the first direction on the channel structure, and extend in the second direction and a gate insulating film between the first channel pattern and the first word line, and between the second channel pattern and the second word line and a first capacitor and a second capacitor which are connected to the first channel pattern and the second channel pattern, on the first channel pattern and the second channel pattern, the back gate structure including a back gate electrode, and a back gate insulating film between the back gate electrode and the channel structure, and a height up to the upper surface of the back gate structure is equal to or smaller than a height up to the upper surface of the first word line, on the basis of the upper surface of the bit line.

According to some aspects of the present disclosure, there is provided a semiconductor memory device including a bit line extending in a first direction on a substrate, a channel structure on the bit line, and includes a first vertical part extending in a second direction, and a second vertical part spaced apart from the first vertical part in the first direction and extending in the second direction, a back gate electrode on the bit line on at least one side of the channel structure, and including a back gate electrode extending in the second direction, and a back gate insulating film between the back gate electrode and the channel structure, an etching stop film between the bit line and the back gate structure, a back gate insulating film between the back gate electrode and the channel structure, a back gate capping film on the back gate electrode and the back gate insulating film, a first word line between the first vertical part and the second vertical part and extending in the second direction, a second word line between the first vertical part and the second vertical part, extending in the second direction, and is spaced apart from the first word line in the first direction, a gate insulating film between the first vertical part and the first word line, and between the second vertical part and the second word line and a first capacitor and a second capacitor connected to the first vertical part and the second vertical part, on the first vertical part and the second vertical part, a height up to an upper surface of the back gate structure being equal to or smaller than a height up to an upper surface of the first word line, on the basis of an upper surface of the bit line.

### BRIEF DESCRIPTION OF DRAWINGS

The above and other aspects and features of the present disclosure will become more apparent by describing in detail illustrative embodiments thereof with reference to the attached drawings, in which:

FIG. 1 is a layout diagram for explaining a semiconductor memory device according to some example embodiments.

FIG. 2 is a cross-sectional view taken along A-A and B-B of FIG. 1.

FIG. 3 is a cross-sectional view taken along C-C and D-D of FIG. 1.

FIG. 4 is an enlarged view of a portion Q of FIG. 2.

FIG. 5 is an enlarged view of a portion P of FIG. 2.

FIGS. 6 to 10 are enlarged views of the portion P of FIG. 2

FIG. 11 is a diagram for explaining a semiconductor memory device according to some example embodiments.

FIGS. 12 to 15 are diagrams for explaining a semiconductor memory device according to some example embodiments.

FIGS. 16 to 18 are diagrams for explaining a semiconductor memory device according to some example embodiments.

FIGS. 19 to 22 are diagrams for explaining a semiconductor memory device according to some example embodiments.

FIGS. 23 to 38 are diagrams for explaining a method for fabricating the semiconductor memory device according to some example embodiments.

### DETAILED DESCRIPTION

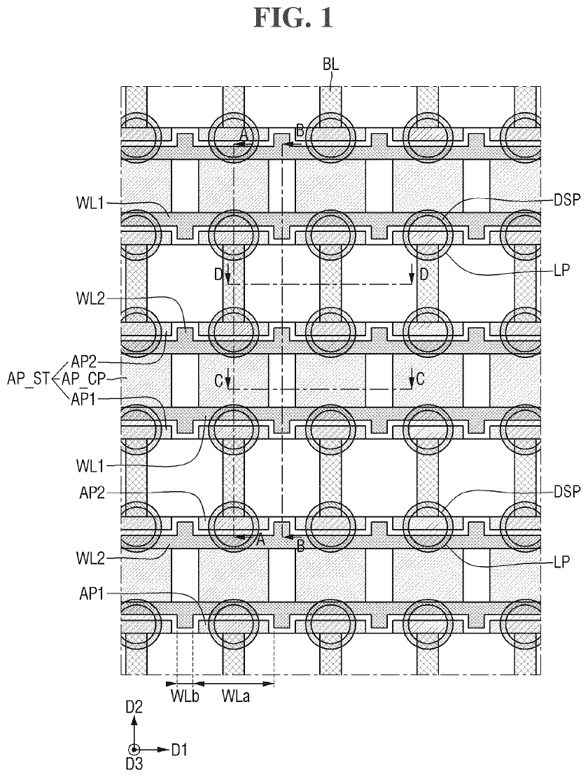

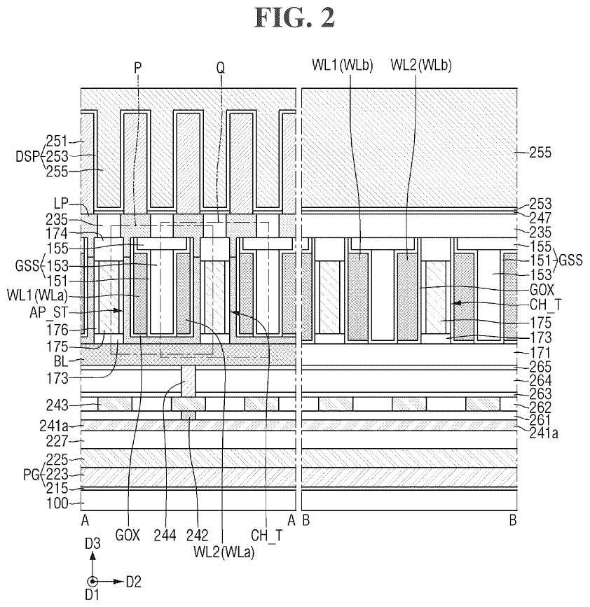

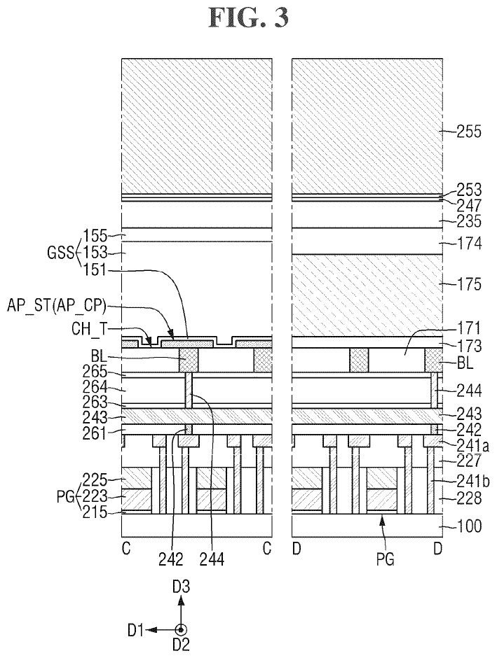

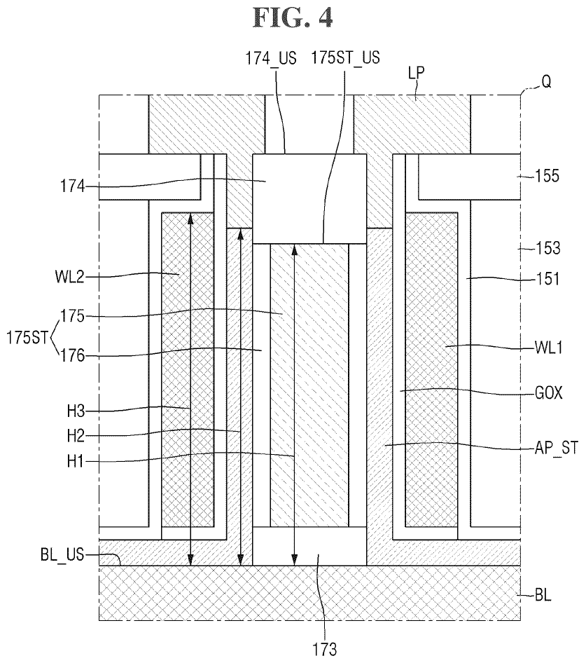

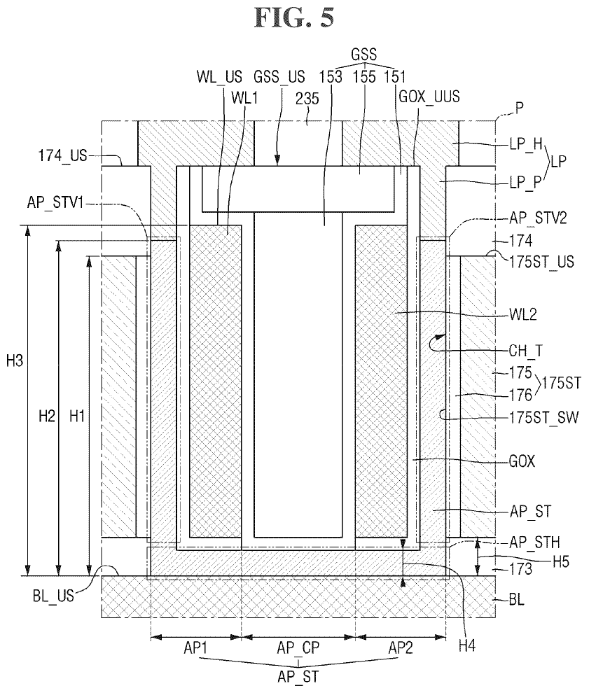

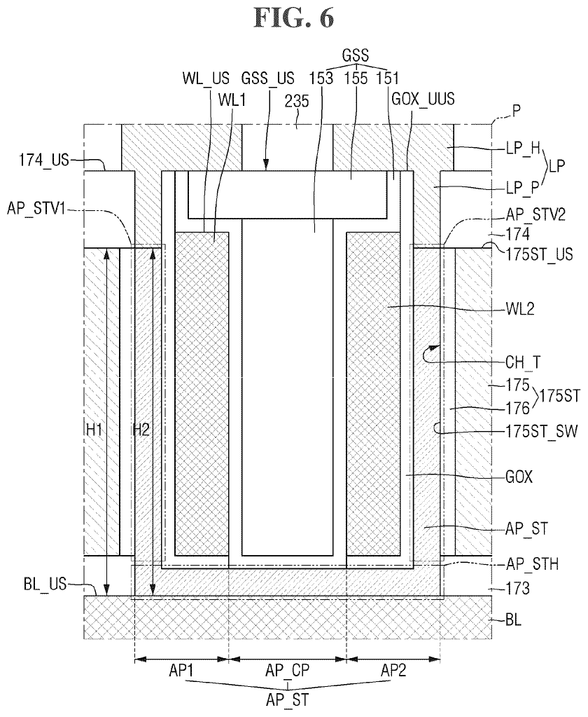

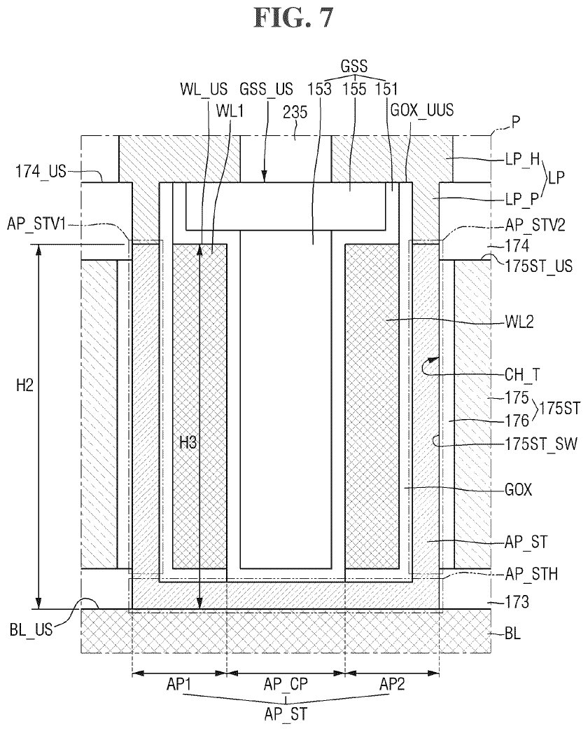

FIG. 1 is a layout diagram for explaining a semiconductor memory device according to some example embodiments. FIG. 2 is a cross-sectional view taken along A-A and B-B of FIG. 1. FIG. 3 is a cross-sectional view taken along C-C and D-D of FIG. 1. FIG. 4 is an enlarged view of a portion Q of FIG. 2. FIG. 5 is an enlarged view of a portion P of FIG. 2. FIGS. 6 to 10 are enlarged views of the portion P of FIG. 2.

The semiconductor memory device according to some example embodiments of the present inventions may include memory cells including a vertical channel transistor (VCT).

Referring to FIGS. 1 to 10, the semiconductor memory device according to some example embodiments may include a peri-gate structure PG, bit lines BL, word lines WL1 and WL2, channel structures AP_ST, a back gate structure 175ST, and data storage patterns DSP.

A substrate 100 may be a silicon substrate, or may include other materials, for example, but not limited to, silicon germanium, indium antimonide, lead telluride, indium arsenide, indium phosphide, gallium arsenide or gallium antimonide.

A peri-gate structure PG may be disposed on the substrate 100. The substrate 100 may include a cell array region and a peripheral circuit region. The peri-gate structure PG may be disposed over the cell array region and the peripheral circuit region. In other words, a part of the peri-gate structure PG is disposed in the cell array region of the substrate 100, and the rest of the peri-gate structure PG may be disposed in the peripheral circuit region of the substrate 100.

The peri-gate structure PG may be included in a sensing transistor, a transfer transistor, a driving transistor, and the like. However, example embodiments are not limited thereto, and the types of transistors disposed in the cell array region and the peripheral circuit region may vary depending on a design and/or purpose of the semiconductor memory device.

The peri-gate structure PG may include a peri-gate insulating film 215, a peri-lower conductive pattern 223, and a peri-upper conductive pattern 225. The peri-gate insulating film 215 may include a silicon oxide film, a silicon oxynitride film, a high dielectric constant insulating film having a dielectric constant higher than that of the silicon oxide film or a combination thereof. The high dielectric constant insulating film may include, for example, but not limited to, at least one of metal oxide, metal oxynitride, metal silicon oxide, and metal silicon oxynitride.

The peri-lower conductive pattern 223 and the peri-upper conductive pattern 225 each include a conductive material. For example, the peri-lower conductive pattern 223 and the peri-upper conductive pattern 225 may each include at least one of a doped semiconductor material, a conductive metal nitride, a conductive metal silicon nitride, a metal carbonitride, a conductive metal silicide, a conductive metal oxide, a two-dimensional material (2D material), a metal, and a metal alloy. Although the peri-gate structure PG is shown to include a plurality of conductive patterns, example embodiments are not limited thereto.

In the semiconductor device according to some example embodiments, the two-dimensional material may be a metallic material and/or a semiconductor material. The 2D material may include a 2D allotrope or a 2D compound, and may include, for example, but not limited to, at least one of graphene, molybdenum disulfide (MoS₂), molybdenum diselenide (MoSe₂), tungsten diselenide (WSe₂), and tungsten disulfide (WS₂). That is, since the above-mentioned 2D materials are only listed as an example, the 2D materials that may be included in the semiconductor memory device of the present inventions are not limited by the above-mentioned materials.

A first peri-lower insulating film 227 and a second peri-lower insulating film 228 are disposed on the substrate 100. The first peri-lower insulating film 227 and the second peri-lower insulating film 228 may each be made of an insulating material.

A first peri-wiring line 241a and a peri-contact plug 241b may be disposed inside the first peri-lower insulating film 227 and the second peri-lower insulating film 228. Although the first peri-wiring line 241a and the peri-contact plug 241b are shown as being different films from each other, example embodiments are not limited thereto. The boundary between the first peri-wiring line 241a and the peri-contact plug 241b may not be distinguished, that is, the first peri-wiring line 241a and the peri-contact plug 241b may be integral. The first peri-wiring line 241a and the peri-contact plug 241b each include a conductive material.

A first peri-upper insulating film 261 and a second peri-upper insulating film 262 may be disposed on the first peri-wiring line 241a and the peri-contact plug 241b. The first peri-upper insulating film 261 and the second peri-upper insulating film 262 may each be made of an insulating material.

A second peri-wiring line 243 and a peri-via plug 242 may be disposed on the first peri-wiring line 241a. The peri-via plug 242 may be disposed in the first peri-upper insulating film 261. The second peri-wiring line 243 may be disposed in the second peri-upper insulating film 262.

The second peri-wiring line 243 and the peri-via plug 242 may be connected to the first peri-wiring line 241a. The peri-via plug 242 may connect the first peri-wiring line 241a and the second peri-wiring line 243. The second peri-wiring line 243 and the peri-via plug 242 each include a conductive material. Although the second peri-wiring line 243 and the peri-via plug 242 are shown as being different films from each other, example embodiments are not limited thereto. The boundary between the second peri-wiring line 243 and the peri-via plug 242 may not be distinguished, that is, the second peri-wiring line 243 and the peri-via plug 242 may be integral.

A third peri-upper insulating film 263, a fourth peri-upper insulating film 264, and a fifth peri-upper insulating film 265 may be sequentially disposed on the second peri-wiring line 243. The third upper peri-insulating film 263, the fourth upper peri-insulating film 264, and the fifth upper peri-insulating film 265 may each be made of an insulating material.

The fourth peri-upper insulating film 264 may be made of an insulating material different from that of the third peri-upper insulating film 263 and the fifth peri-upper insulating film 265. For example, the fourth upper peri-insulating film 264 may be made of an oxide-based insulating material, and the third upper peri-insulating film 263 and the fifth upper peri-insulating film 265 may be made of a nitride-based insulating material, but example embodiments are not limited thereto.

A cell connection plug 244 may be disposed in the third peri-upper insulating film 263, the fourth peri-upper insulating film 264, and the fifth peri-upper insulating film 265. The cell connection plug 244 may be connected to the second peri-wiring line 243. The cell connection plug 244 includes a conductive material. In some example embodiments, a peri-upper insulating film made of a single layer may be disposed in the cell connection plug 244, which is not shown.

The bit lines BL are disposed on the peri-gate structure PG. In some example embodiments, the bit lines BL may be disposed on the fifth peri-upper insulating film 265. For example, the bit lines BL may be in contact with the fifth peri-upper insulating film 265.

The bit line BL may extend long in a second direction D2. Adjacent bit lines BL may be spaced apart in a first direction D1. The bit line BL includes a long side wall extending in the second direction D2 and a single side wall extending in the first direction D1.

Although not shown, each bit line BL may extend from the cell array region to the peripheral circuit region. The end of each bit line BL may be disposed on the peripheral circuit region of the substrate 100.

Each bit line BL may be disposed on the cell connection plug 244. Each bit line BL may be connected to the cell connection plug 244. Each bit line BL may include, for example, at least one of a doped semiconductor material, a conductive metal nitride, a conductive metal silicon nitride, a metal carbonitride, a conductive metal silicide, a conductive metal oxide, a two-dimensional material, a metal, and a metal alloy. Although each bit line BL is shown to be a single film, example embodiments are not limited thereto.

A cell lower insulating film 171 may be disposed on the fifth peri-upper insulating film 265. The cell lower insulating film 171 is disposed between the bit lines BL spaced apart in the first direction D1. The cell lower insulating film 171 may be made of an insulating material.

An etching stop film 173 may be disposed between a back gate structure 175ST and a cell lower insulating film 171, which will be described later. The etching stop film 173 may be disposed between the back gate structure 175ST and the bit line BL. The etching stop film 173 may include a material having an etching selectivity with respect to the back gate electrode 175.

A side wall of the etching stop film 173 may be in contact with a channel structure AP_ST, which will be described below. The back gate structure 175ST may not be disposed between the etching stop film 173 and the channel structure AP_ST.

The back gate structure 175ST may be disposed on the bit line BL and the cell lower insulating film 171. The back gate structure 175ST may be disposed on the etching stop film 173. The back gate structure 175ST may include a plurality of channel trenches CH_T. Each channel trench CH_T may extend long in the first direction D1. Adjacent channel trenches CH_T may be spaced apart in the second direction D2.

Each channel trench CH_T intersects the bit line BL. One channel trench CH_T may expose a plurality of bit lines BL adjacent in the first direction D1.

A lower surface of each channel trench CH_T may be defined by the bit line BL and the cell lower insulating film 171. The side wall of each channel trench CH_T may be defined by the etching stop film 173, the back gate structure 175ST and the back gate capping film 174. At least a part of the side wall of the channel trench CH_T may be the side wall of a back gate insulating film 176. If the etching stop film 173 is not disposed, the side walls of each channel trench CH_T may be defined by the back gate structure 175ST and the back gate capping film 174.

The back gate structure 175ST may include the back gate electrode 175 and the back gate insulating film 176.

The back gate electrode 175 may be disposed on the etching stop film 173. The back gate electrode 175 may be in contact with the upper surface of the etching stop film 173. The back gate electrode 175 may extend in a third direction D3.

As an example, the back gate electrode 175 may include polysilicon including impurities. The impurities may include, for example, at least one of N-type and P-type impurities. As another example, the back gate electrode 175 may include a conductive metal. However, example embodiments are not limited thereto.

The back gate insulating film 176 may be disposed on the upper surface of the etching stop film 173 and side walls of the back gate electrode 175. The back gate insulating film 176 may extend along side walls of the back gate electrode 175. The back gate insulating film 176 may be in contact with the upper surface of the etching stop film 173. One side wall of the back gate insulating film 176 may be disposed on the back gate electrode 175. Another side wall of the back gate insulating film 176 may be disposed on the channel structure AP_ST.

The back gate electrode 175 and the back gate insulating film 176 may completely cover the upper surface of the etching stop film 173.

The back gate insulating film 176 may include an insulating material. As an example, if the back gate electrode 175 includes polysilicon, the back gate insulating film 176 may include silicon oxide. As another example, if the back gate electrode 175 includes a conductive metal, the back gate insulating film 176 may include an oxide of the metal included in the back gate electrode 175.

On the basis of the upper surface BL_US of the bit line BL, the back gate structure 175ST may have a first height H1 up to the upper surface 175ST_US of the back gate structure 175ST. The upper surface of the back gate electrode 175 and the upper surface of the back gate insulating film 176 may be disposed on the same plane. In other words, on the basis of the upper surface BL_US of the bit line BL, the height up to the upper surface of the back gate electrode 175 and the height up to the upper surface of the back gate insulating film 176 may be equal to a first height H1.

The back gate capping film 174 may be disposed on the back gate structure 175ST. The back gate capping film 174 may extend along the upper surface 175ST_US of the back gate structure 175ST. The back gate capping film 174 may cover the upper surface of the back gate electrode 175 and the upper surface of the back gate insulating film 176.

In some example embodiments, a part of the back gate capping film 174 may overlap a part of the first vertical part AP_STVI of the channel structure AP_ST, which will be described later, in the first direction D1. However, example embodiments are not limited thereto.

The back gate capping film 174 may include an insulating material. The back gate capping film 174 may include, for example, a silicon nitride-based insulating material. However, example embodiments are not limited thereto.

The channel structure AP_ST may be disposed on each bit line BL. A plurality of channel structures AP_ST may be connected to one bit line BL. The plurality of channel structures AP_ST disposed on one bit line BL are spaced apart in the second direction D2.

The channel structure AP_ST may be disposed in the channel trench CH_T extending in the first direction D1. The plurality of channel structures AP_ST may be disposed in one channel trench CH_T. The plurality of channel structures AP_ST disposed in the channel trench CH_T are spaced apart in the first direction D1.

For example, the channel structures AP_ST may be arranged two-dimensionally along the first direction D1 and the second direction D2 that intersect each other.

The channel structure AP_ST may extend along the side walls and lower surface of the channel trench CH_T. In a cross-section taken in the second direction D2, the channel structure AP_ST may have a “U” shape.

The channel structure AP_ST may include a horizontal part AP_STH, a first vertical part AP_STV1, and a second vertical part AP_STV2. The first vertical part AP_STV1 of the channel structure AP_ST and the second vertical part AP_STV2 of the channel structure AP_ST may protrude in the third direction D3 from the horizontal part AP_STH of the channel structure AP_ST.

The horizontal part AP_STH of the channel structure AP_ST may extend along the lower surface of the channel trench CH_T. In the cross-section taken along the second direction D2, the horizontal part AP_STH of the channel structure AP_ST may extend along the upper surface of the bit line BL. The horizontal part AP_STH of the channel structure AP_ST is connected to the bit line BL. For example, the horizontal part AP_STH of the channel structure AP_ST may be in contact with the upper surface BL_US of the bit line BL.

The first vertical part AP_STV1 of the channel structure AP_ST and the second vertical part AP_STV2 of the channel structure AP_ST may extend along side walls of the channel trench CH_T. In a cross-section taken along the second direction D2, the first vertical part AP_STV1 of the channel structure AP_ST and the second vertical part AP_STV2 of the channel structure AP_ST may each extend along side walls 175ST_SW of the back gate structure 175ST.

The channel structure AP_ST may include an oxide semiconductor material. The channel structure AP_ST may include, for example, metal oxide. As an example, the channel structure AP_ST may be an amorphous metal oxide film. As another example, the channel structure AP_ST may be a polycrystalline metal oxide film. As yet another example, the channel structure AP_ST may be in a state in which the amorphous metal oxide film and the polycrystalline metal oxide film are combined. As another example, the channel structure AP_ST may be a CAAC (c-axis aligned crystalline) metal oxide film.

The channel structure AP_ST may include, for example, but not limited to, at least one of indium oxide, tin oxide, zinc oxide, In-Zn-based oxide (IZO), Sn-Zn-based oxide, Al-Zn-based oxide, Zn-Mg-based oxide, Sn-Mg-based oxide, In-Mg-based oxide, In-Ga-based oxide (IGO), In-Ga-Zn-based oxide (IGZO), In-Al-Zn-based oxide, In-Sn-Zn-based oxide, Sn-Ga-Zn-based oxide, Al-Ga-Zn-based oxide, Sn-Al-Zn-based oxide, In-Hf-Zn-based oxide, In-La-Zn-based oxide, In-Ce-Zn-based oxide, In-Pr-Zn-based oxide, In-Nd-Zn-based oxide, In-Sm-Zn-based oxide, In-Eu-Zn-based oxide, In-Gd-Zn-based oxide, In-Tb-Zn-based oxide, In-Dy-Zn-based oxide, In-Ho-Zn-based oxide, In-Er-Zn-based oxide, In-Tm-Zn-based oxide, In-Yb-Zn-based oxide, In-Lu-Zn-based oxide, In-Sn-Ga-Zn-based oxide, In-Hf-Ga-Zn-based oxide, In-Al-Ga-Zn-based oxide, In-Sn-Al-Zn-based oxide, In-Sn-Hf-Zn-based oxide, and In-Hf-Al-Zn-based oxide.

Here, the In-Ga-Zn-based oxide means an oxide that has In, Ga, and Zn as main components, but does not refer to a singular ratio of In, Ga, and Zn. That is, taking IGZO (indium gallium zinc oxide) as an example, the channel structure AP_ST may include IGZO (indium gallium zinc oxide, InₓGa_{y}Zn_{z}O). The IGZO (In:Ga:Zn=1:1:1) containing indium, gallium and zinc at the same ratio may be an In-Ga-Zn-based oxide. A Ga-rich IGZO may have a higher ratio of gallium than the IGZO (In:Ga:Zn=1:1:1), and a lower ratio of indium than the IGZO (In:Ga:Zn=1:1:1). The Ga-rich IGZO may also be an In-Ga-Zn-based oxide. An In-rich IGZO may also have a higher ratio of indium than IGZO (In:Ga:Zn=1:1:1) and a lower ratio of gallium than IGZO (In:Ga:Zn=1:1:1). In-rich IGZO may also be an In-Ga-Zn-based oxide.

Although the above description has been made using the IGZO, the present inventions are not limited thereto. Needless to say, the above description may be applied when the channel structures AP_ST each include a ternary or higher metal oxide. Also, when the channel structure AP_ST includes the In-Ga-Zn-based oxide, the channel structure AP_ST may further include a doped metal element other than In, Ga, and Zn.

The channel structure AP_ST may include a first channel pattern AP1, a second channel pattern AP2, and a connecting channel pattern AP_CP. The connecting channel pattern AP_CP connects the first channel pattern AP1 and the second channel pattern AP2. The first channel pattern AP1 and the second channel pattern AP2 are spaced apart in the second direction D2.

The first channel pattern AP1, the second channel pattern AP2, and the connecting channel pattern AP_CP are disposed on the bit line BL. The first channel pattern AP1 and the second channel pattern AP2 are connected to the bit line BL. The first channel pattern AP1 and the second channel pattern AP2 may be in contact with the upper surface of the bit line BL.

The first channel pattern AP1 may include a part of the horizontal part AP_STH of the channel structure AP_ST, and the first vertical part AP_STV1 of the channel structure. A part of the horizontal part AP_STH of the channel structure AP_ST may be a horizontal part of the first channel pattern AP1. The first vertical part AP_STV1 of the channel structure AP_ST may be a vertical part of the first channel pattern AP1.

The second channel pattern AP2 may include another part of the horizontal part AP_STH of the channel structure AP_ST, and the second vertical part AP_STV2 of the channel structure AP_ST. Another part of the horizontal part AP_STH of the channel structure AP_ST may be the horizontal part of the second channel pattern AP2. The second vertical part AP_STV2 of the channel structure AP_ST may be the vertical part of the second channel pattern AP2.

The connecting channel pattern AP_CP includes the rest of the horizontal part AP_STH of the channel structure AP_ST.

The horizontal part AP_STH of the channel structure AP_ST may have a fourth height H4. Here, the fourth height H4 may be the thickness of the horizontal part AP_STH of the channel structure AP_ST in the third direction D3. The etching stop film 173 may have a fifth height H5. Here, the fifth height H5 may be a thickness of the etching stop film 173 in the third direction D3. In other words, the fifth height H5 may be a height up to the upper surface of the etching stop film 173 on the basis of the upper surface BL_US of the bit line BL. In some example embodiments, the fifth height H5 may be greater than the fourth height H4. However, example embodiments are not limited thereto. For example, the fifth height H5 may be the same as the fourth height H4.

Uppermost parts of the vertical parts AP_STV1 and AP_STV2 of the channel structure AP_ST may have a second height H2 on the basis of the upper surface BL_US of the bit line BL. The uppermost parts of the vertical parts AP_STV1 and AP_STV2 of the channel structure AP_ST may be disposed to be higher than the upper surface 175ST_US of the back gate structure 175ST. That is, the first height H1 of the back gate structure 175ST may be smaller than the second height H2 of the vertical parts AP_STV1 and AP_STV2 of the channel structure AP_ST.

In the semiconductor memory device according to some example embodiments, as in FIG. 6, the first height Hl of the back gate structure 175ST may be the same as the second height H2 of the vertical parts AP_STV1 and AP_STV2 of the channel structure AP_ST.

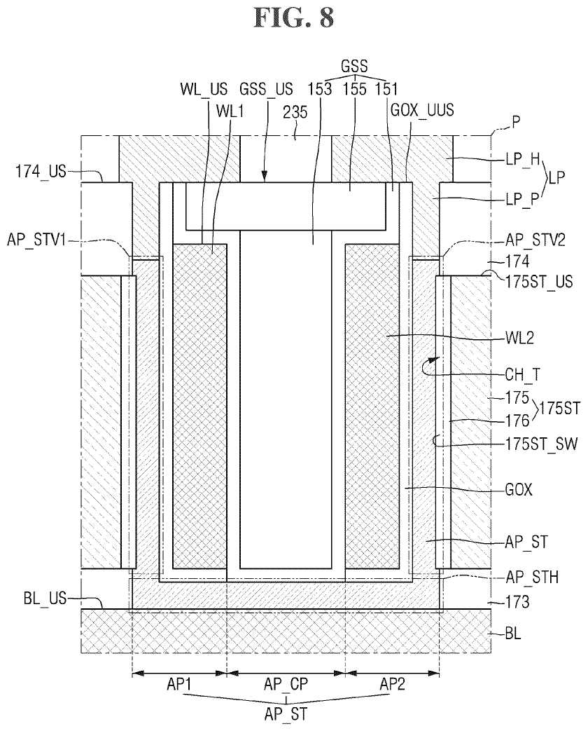

In the semiconductor memory device according to some example embodiments, a part of the back gate insulating film 176 may protrude toward the channel structure AP_ST, as in FIG. 8.

The side walls of the back gate capping film 174 and the side walls of the back gate insulating film 176 may not be disposed on the same line. For example, the back gate insulating film 176 may protrude beyond the side walls of the back gate capping film 174 in the second direction D2. The side walls of the etching stop film 173 and the side walls of the back gate insulating film 176 may not be disposed on the same line. For example, the back gate insulating film 176 may protrude beyond the side walls of the etching stop film 173 in the second direction D2.

Unlike FIG. 5, each of the first vertical part AP_STV1 of the channel structure AP_ST and the second vertical part AP_STV2 of the channel structure AP_ST may include a recessed portion. The back gate insulating film 176 may fill the recessed portion.

The first channel pattern AP1, the second channel pattern AP2, and the connecting channel pattern AP_CP may be distinguished on the basis of a first word line WL1 and a second word line WL2, which will be described later. In FIG. 4, the first word line WL1 will be described as an example. The first word line WL1 may include an inner side wall that faces the side wall 175ST_SW of the back gate structure 175ST, and an outer side wall opposite to the inner side wall in the second direction D2. The boundary between the first channel pattern AP1 and the connecting channel pattern AP_CP may be an extension line of the outer wall of the first word line WL1 extending in the third direction D3.

The first word line WL1 and the second word line WL2 may be disposed on the channel structure AP_ST. The first word line WL1 and the second word line WL2 may be disposed in the channel trench CH_T.

Each of the first word line WL1 and the second word line WL2 may extend in the first direction D1. The first word line WL1 and the second word line WL2 may be alternately arranged in the second direction D2. The first word line WL1 is spaced apart from the second word line WL2 in the second direction D2.

The first word line WL1 and the second word line WL2 are spaced apart from the bit line BL in the third direction D3. The first word line WL1 and the second word line WL2 intersect the bit line BL.

The first word line WL1 and the second word line WL2 are disposed on the horizontal part AP_STH of the channel structure. The first word line WL1 and the second word line WL2 are disposed between the first vertical part AP_STV1 of the channel structure AP_ST and the second vertical part AP_STV2 of the channel structure AP_ST.

The first word line WL1 is disposed on the first channel pattern AP1. The second word line WL2 is disposed on the second channel pattern AP2. The first word line WL1 and the second word line WL2 are disposed between the first channel pattern AP1 and the second channel pattern AP2. The first channel pattern AP1 is closer to the first word line WL1 than the second word line WL2. The second channel pattern AP2 is closer to the second word line WL2 than the first word line WL1.

Each of the first word line WL1 and the second word line WL2 may have a width in the second direction D2. The width of the first word line WL1 in the portion that overlaps the channel structure AP_ST in the third direction D3 may be different from the width of the first word line WL1 in the portion that does not overlap the channel structure AP_ST. The width of the second word line WL2 in the portion that overlaps the channel structure AP_ST in the third direction D3 may be different from the width of the second word line WL2 in the portion that does not overlap the channel structure AP_ST.

For example, each of the first word line WL1 and the second word line WL2 may include a first portion Wla of the word line and a second portion WLb of the word line. The width of the first portion Wla of the word line in the second direction D2 may be smaller than the width of the second portion WLb of the word line in the second direction D2. As an example, the first portion Wla of the word line may be disposed on the channel structure AP_ST. The first portion Wla of the word line may be disposed on the first channel pattern AP1 and the second channel pattern AP2.

Each of the first word line WL1 and the second word line WL2 may include the first portion Wla of the word line and the second portion WLb of the word line that are alternately disposed along the first direction D1. Each channel structure AP_ST may be disposed between second portions WLb of the word line adjacent in the first direction D1. In the first word line WL1, each first active pattern AP1 may be disposed between second portions WLb of the word line adjacent in the first direction D1. In the second word lines WL2, each second active pattern AP2 may be disposed between the second portions WLb of the word line adjacent in the first direction D1.

The channel structure AP_ST is not disposed below the second portion WLb of the word line. The height of the first portion Wla of the word line is smaller than the height of the second portion WLb of the word line.

The first and second word lines WL1 and WL2 include a conductive material, and may include, for example, at least one of doped polysilicon, conductive metal nitride, conductive metal silicon nitride, metal carbonitride, conductive metal silicide, conductive metal oxide, two-dimensional material, metal, and metal alloy.

The first and second word lines WL1 and WL2 may include an upper surface WL_US and a lower surface that are opposite to each other in the third direction D3. The lower surfaces of the first and second word lines WL1 and WL2 face the bit line BL.

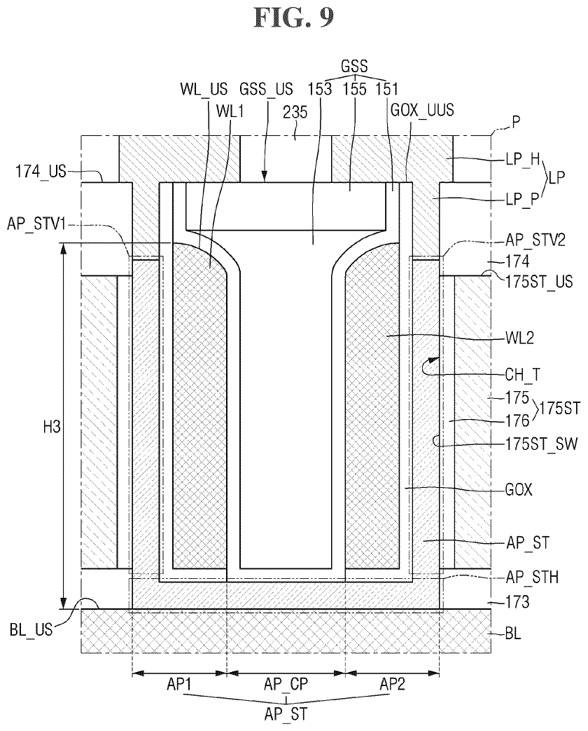

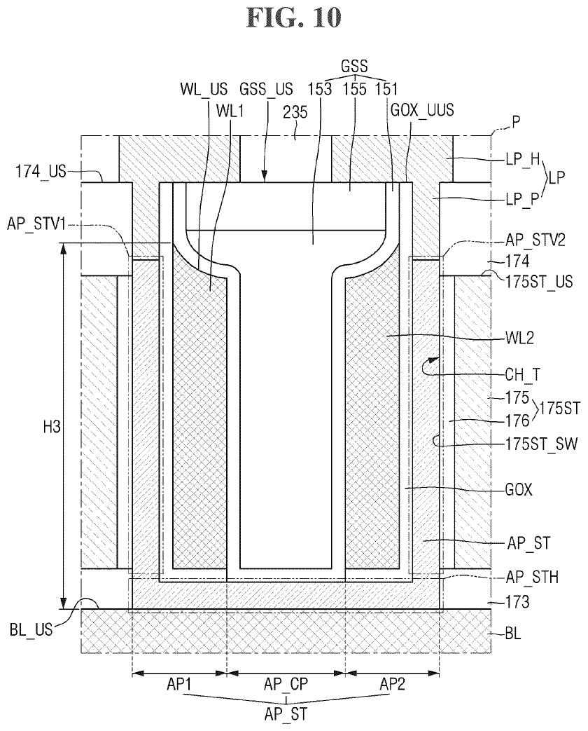

In FIG. 5, the upper surface WL_US of the first and second word lines WL1 and WL2 may be a plane. In FIG. 9, the upper surface WL_US of the first and second word lines WL1 and WL2 may be convexly rounded. In FIG. 10, the upper surface WL_US of the first and second word lines WL1 and WL2 may be concavely rounded.

On the basis of the upper surface BL_US of the bit line BL, the upper surface WL_US of the first and second word lines WL1 and WL2 may be higher than the uppermost parts of the vertical parts AP_STV1 and AP_STV2 of the channel structure AP_ST. The uppermost parts of the channel patterns AP1 and AP2 may be the uppermost parts of the vertical parts AP_STV1 and AP_STV2 of the channel structure AP_ST. The first and second word lines WL1 and WL2 may have a third height H3 from the upper surface BL_US of the bit line BL to the upper surface WL_US of the first and second word lines WL1 and WL2. A second height H2 up to the uppermost parts of the vertical parts AP_STV1 and AP_STV2 of the channel structure AP_ST may be smaller than the third height H3 up to the upper surface WL_US of the first and second word lines WL1 and WL2.

In the semiconductor memory device according to some example embodiments, the second height H2 up to the uppermost part of the vertical parts AP_STV1 and AP_STV2 of the channel structure AP_ST may be equal to the third height H3 up to the upper surfaces WL_US of the first and second word lines WL1 and WL2.

A gate insulating film GOX may be disposed between the first word line WL1 and the channel structure AP_ST, and between the second word line WL2 and the channel structure AP_ST. The gate insulating film GOX may be disposed between the first word line WL1 and the first active pattern AP1, and between the second word line WL2 and the second active patterns AP2. The gate insulating film GOX may extend in the first direction D1 along with the first word line WL1 and the second word line WL2.

The gate insulating film GOX may extend along the first vertical part AP_STV1 of the channel structure. The gate insulating film GOX may extend along the second vertical part AP_STV2 of the channel structure. In the semiconductor memory device according to some example embodiments, the gate insulating film GOX may not be disposed on the horizontal part AP_STH of the channel structure AP_ST that does not overlap the first word line WL1 and the second word line WL2 in the third direction D3. From the viewpoint of the cross-sectional view, the gate insulating film GOX between the first word line WL1 and the channel structure AP_ST may be separated from the gate insulating film GOX between the second word line WL2 and the channel structure AP_ST.

The gate insulating film GOX may include a silicon oxide film, a silicon oxynitride film, a high dielectric constant insulating film having a higher dielectric constant than the silicon oxide film, or a combination thereof.

A part of the gate insulating film GOX may protrude beyond the upper surfaces WL_US of the first and second word lines WL1 and WL2 in the third direction D3. A part of the gate insulating film GOX may protrude beyond the uppermost parts of the vertical parts AP_STV1 and AP_STV2 of the channel structure in the third direction D3.

A height from the upper surface BL_US of the bit line BL to the uppermost part GOX_UUS of the gate insulating film may be greater than the second height H2 from the upper surface BL_US of the bit line BL to the uppermost parts of the vertical parts AP_STV1 and AP_STV2 of the channel structure AP_ST. The height from the upper surface of the bit line BL to the uppermost part GOX_UUS of the gate insulating film may be greater than the third height H3 from the upper surface of the bit line BL to the upper surface WL_US of the word lines WL1 and WL2.

A gate separation pattern GSS may be disposed on the bit line BL and the cell lower insulating film 171. The gate separation pattern GSS may be disposed inside the channel trench CH_T. The gate separation pattern GSS may be disposed on the channel structure AP_ST, the first word line WL1 and the second word line WL2.

In the semiconductor memory device according to some example embodiments, the gate separation pattern GSS may be in contact with the channel structure AP_ST. The gate separation pattern GSS may be disposed on the connecting channel pattern AP_CP. The gate separation pattern GSS may be in contact with the horizontal part AP_STH of the channel structure. The gate separation pattern GSS may be spaced apart from the bit line BL in the third direction D3.

The gate separation pattern GSS may be disposed between the first word line WL1 and the second word line WL2 adjacent in the second direction D2. The first word line WL1 and the second word line WL2 may be separated by the gate separation pattern GSS. The gate separation pattern GSS may extend in the first direction D1 between the first word line WL1 and the second word line WL2.

The first word line WL1 may be disposed between the gate separation pattern GSS and the channel structure AP_ST. The second word line WL2 may be disposed between the gate separation pattern GSS and the channel structure AP_ST. The first word line WL1 may be disposed between the gate separation pattern GSS and the first channel pattern AP1. The second word line WL2 may be disposed between the gate separation pattern GSS and the second channel pattern AP2.

The gate separation pattern GSS may include a horizontal part and a protruding part. The protruding part of the gate separation pattern GSS may protrude from the horizontal part of the gate separation pattern GSS toward the bit line BL in the third direction D3. The protruding part of the gate separation pattern GSS may be closer to the bit line BL than the horizontal part of the gate separation pattern GSS. The horizontal part of the gate separation pattern GSS may be disposed on the upper surface WL_US of the first and second word lines WL1 and WL2. In a cross-sectional view, the gate separation pattern GSS may have a “T” shape.

The gate separation pattern GSS may include a gate separation liner 151, a gate separation filling film 153 and a gate separation capping film 155. The gate separation liner 151 may extend along upper surfaces WL_US of the first and second word lines WL1 and WL2 and outer walls of the first and second word lines WL1 and WL2. The gate separation liner 151 may extend along the horizontal part AP_STH of the channel structure. The gate separation liner 151 may be in contact with the connecting channel pattern AP_CP. The gate separation liner 151 may extend along the gate insulating film GOX protruding beyond the upper surface WL_US of the first and second word lines WL1 and WL2. Unlike the shown example, the gate separation liner 151 may not extend along the gate insulating film GOX protruding beyond the upper surface WL_US of the first and second word lines WL1 and WL2.

The gate separation filling film 153 may be disposed on the gate separation liner 151. The gate separation capping film 155 may be disposed on the gate separation filling film 153. The gate separation liner 151, the gate separation filling film 153, and the gate separation capping film 155 may each be made of an insulating material. Unlike the shown example, the gate separation pattern GSS may be a single film.

On the basis of the upper surface of the bit line BL, the upper surface GSS_US of the gate separation pattern may be disposed at the same height as the upper surface of the back gate structure 175ST, but is not limited thereto.

A height from the upper surface BL_US of the bit line BL to the upper surface GSS_US of the gate separation pattern may be greater than the second height H2 from the upper surface BL_US of the bit line BL to the uppermost parts of the vertical parts AP_STV1 and AP_STV2 of the channel structure AP_ST. The height from the upper surface BL_US of the bit line BL to the upper surface GSS_US of the gate separation pattern GSS may be greater than the third height H3 from the upper surface BL_US of the bit line BL to the upper surfaces WL_US of the word lines WL1 and WL2.

The height from the upper surface BL_US of the bit line BL to the upper surface GSS_US of the gate separation pattern may be the same as the height from the upper surface BL_US of the bit line BL to the upper surface 174_US of the back gate capping film 174.

Although the height from the upper surface BL_US of the bit line BL to the upper surface GSS_US of the gate separation pattern GSS is shown as being the same as the height from the upper surface BL_US of the bit line BL to the uppermost part GOX_UUS of the gate insulating film GOX, example embodiments are not limited thereto.

The landing pads LP may be disposed on the channel structure AP_ST. The landing pads LP are connected to the first vertical part AP_STV1 of the channel structure and the second vertical part AP_STV2 of the channel structure.

The landing pads LP may be disposed on the first channel pattern AP1 and the second channel pattern AP2. The landing pads LP are connected to the first channel pattern AP1 and the second channel pattern AP2.

From the planar viewpoint, the landing pads LP may have various shapes such as a circular shape, an oval shape, a rectangular shape, a square shape, a rhombic shape, and/or a hexagonal shape.

The landing pads LP may include a horizontal part LP_H and a protruding part LP_P. The horizontal part LP_H of the landing pad may be disposed on the upper surface of the back gate capping film 174 and the upper surface GSS_US of the gate separation pattern. The protruding part LP_P of the landing pad may protrude from the horizontal part LP_H of the landing pad toward the bit line BL in the third direction D3.

On the basis of the upper surface BL_US of the bit line BL, the lowermost part of the landing pad LP may be lower than the upper surface GSS_US of the gate separation pattern. In other words, the protruding part LP_P of the landing pad is disposed between the back gate capping film 174 and the gate separation pattern GSS. The height from the upper surface BL_US of the bit line BL to the lowermost part of the landing pad LP may be smaller than the height from the upper surface BL_US of the bit line BL to the uppermost part GOX_UUS of the gate insulating film.

Pad separation insulating patterns 235 may be disposed between the landing pads LP. From the planar viewpoint, the landing pads LP may be arranged in the form of a matrix along the first direction D1 and the second direction D2. The upper surface of the landing pad LP may be coplanar with the upper surface of the pad separation insulating pattern 245, but is not limited thereto.

The landing pad LP includes a conductive material. The landing pad LP may include, for example, at least one of doped polysilicon, conductive metal nitride, conductive metal silicon nitride, metal carbonitride, conductive metal silicide, conductive metal oxide, two-dimensional material, metal, and metal alloy.

The data storage patterns DSP may be disposed on the landing pads LP, respectively. The data storage patterns DSP may be connected to the first vertical part AP_STV1 of the channel structure AP_ST and the second vertical part AP_STV2 of the channel structure AP_ST. The data storage patterns DSP may be connected to each of the first and second channel patterns AP1 and AP2.

The data storage patterns DSP may be arranged in the form of a matrix along the first direction D1 and the second direction D2, as shown in FIG. 1. The data storage patterns DSP may completely or partially overlap the landing pads LP in the third direction D3. The data storage patterns DSP may be in contact with all or part of the upper surfaces of the landing pads LP.

As an example, the data storage patterns DSP may be capacitors. The first channel pattern AP1 may be connected to the first capacitor. The second channel pattern AP2 may be connected to the second capacitor.

The data storage patterns DSP may include a capacitor dielectric film 253 interposed between the storage electrodes 251 and the plate electrode 255. In such a case, the storage electrode 251 may be in contact with the landing pad LP. From the planar viewpoint, the storage electrode 251 may have various shapes such as a circular shape, an oval shape, a rectangular shape, a square shape, a rhombic shape, and a hexagonal shape. The data storage patterns DSP may completely or partially overlap the landing pads LP. The data storage patterns DSP may be in contact with all or part of the upper surfaces of the landing pads LP. The storage electrodes 251 may penetrate the cell upper etching stop film 247. The cell upper etching stop film 247 may be made of an insulating material.

In contrast, the data storage patterns DSP may be variable resistance patterns that may be switched between two resistance states by electrical pulses applied to the memory elements. For example, the data storage patterns DSP may include a phase-change material, perovskite compounds, transition metal oxide, magnetic materials, ferromagnetic materials, or antiferromagnetic materials in which a crystalline state changes depending on the amount of current.

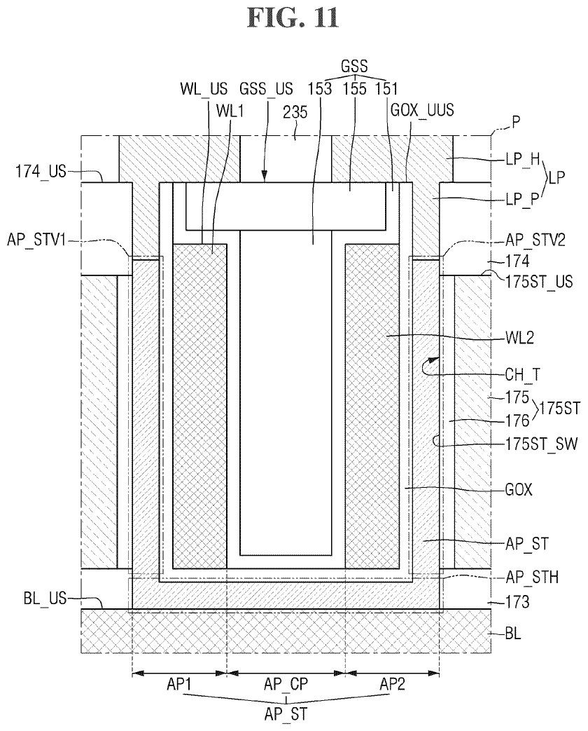

FIG. 11 is a diagram for explaining a semiconductor memory device according to some example embodiments. For convenience of explanation, the points different from those explained in FIGS. 1 to 10 will be mainly explained. For reference, FIG. 11 is an enlarged view of a portion P of FIG. 2.

Referring to FIG. 11, in the semiconductor memory device according to some example embodiments, the gate separation pattern GSS is not in contact with the channel structure AP_ST.

A part of the gate insulating film GOX may be disposed between the gate separation pattern GSS and the channel structure AP_ST. From the viewpoint of the cross-sectional view, the gate insulating film GOX between the first word line WL1 and the channel structure AP_ST may be connected to the gate insulating film GOX between the second word line WL2 and the channel structure AP_ST.

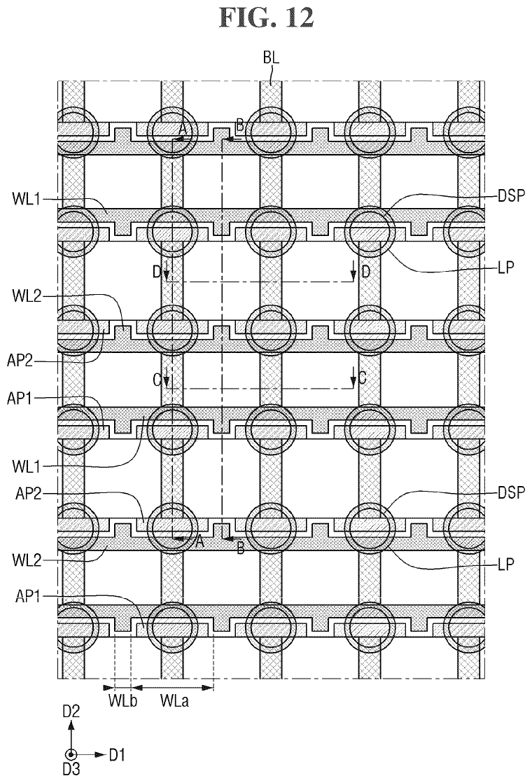

FIGS. 12 to 15 are diagrams for explaining a semiconductor memory device according to some example embodiments. For convenience of explanation, the explanation will focus on points that are different from those explained using FIGS. 1 to 10.

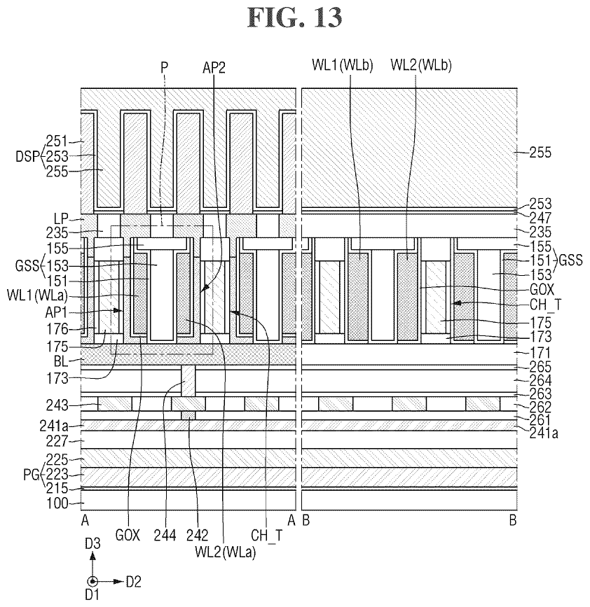

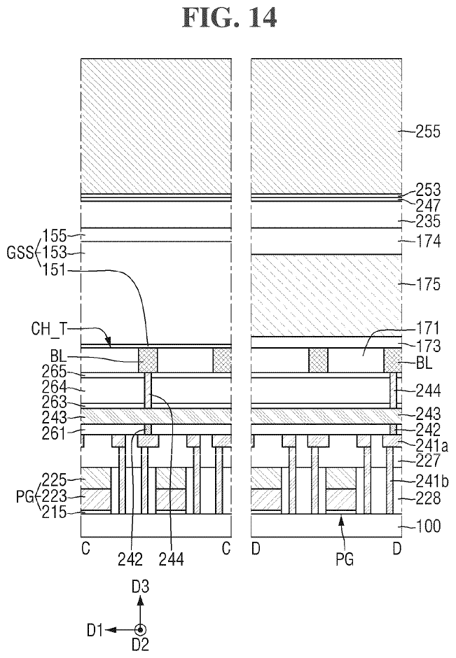

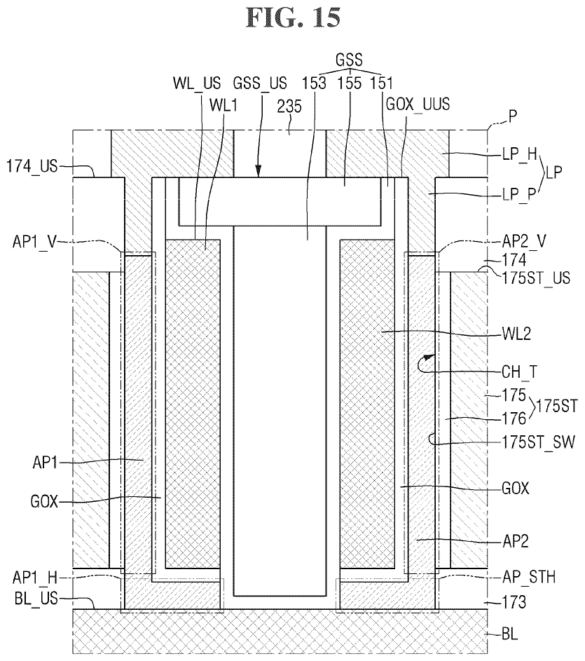

For reference, FIG. 12 is a layout diagram for explaining a semiconductor memory device according to some example embodiments. FIG. 13 is a cross-sectional view taken along A-A and B-B of FIG. 12. FIG. 14 is a cross-sectional view taken along C-C and D-D of FIG. 12. FIG. 15 is an enlarged view of a portion P of FIG. 13.

Referring to FIGS. 12 to 15, in the semiconductor memory device according to some example embodiments, the first channel pattern AP1 and the second channel pattern AP2 spaced apart in the second direction D2 are not connected to each other inside the channel trench CH_T.

The first channel pattern AP1 may include a horizontal part AP1_H extending along the upper surface of the bit line BL, and a vertical part AP1_V extending along side walls of the back gate structure 175ST. The vertical part AP1_V of the first channel pattern may protrude from the horizontal part AP1_H of the first channel pattern in the third direction D3.

The second channel pattern AP2 may include a horizontal part AP2_H extending along the upper surface of the bit line BL, and a vertical part AP2_V extending along side walls of the back gate structure 175ST. The vertical part AP2_V of the second channel pattern may protrude in the third direction D3 from the horizontal part AP2_H of the second channel pattern.

The gate separation pattern GSS may be in contact with the upper surface BL_US of the bit line BL. The horizontal part AP2_H of the second channel pattern and the horizontal part AP1_H of the first channel pattern may be spatially separated by the gate separation pattern GSS. The gate separation liner 151 may be in contact with the upper surface BL_US of the bit line BL.

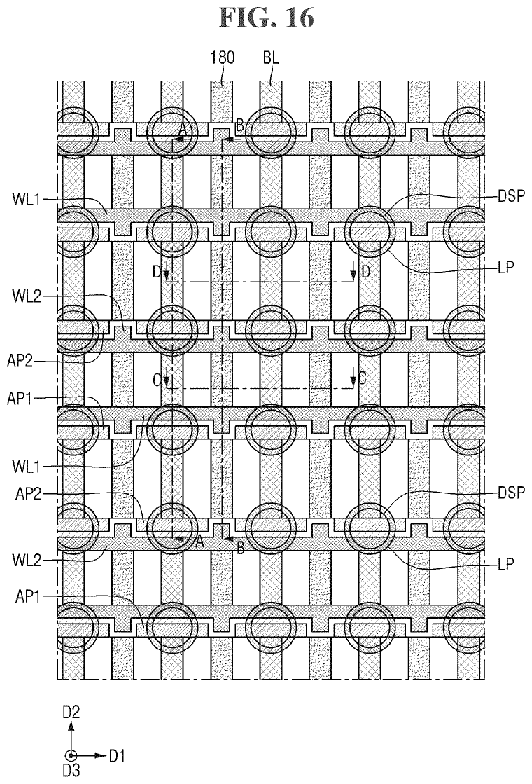

FIGS. 16 to 18 are diagrams for explaining a semiconductor memory device according to some example embodiments. For convenience of explanation, the explanation will focus on points that are different from those explained using FIGS. 1 to 10.

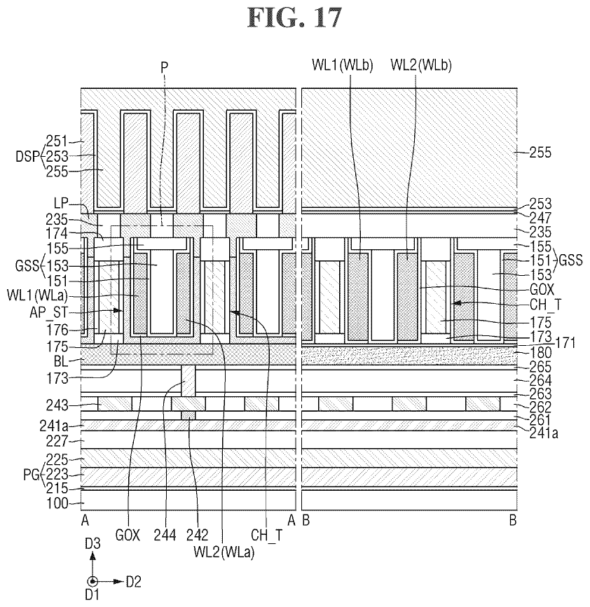

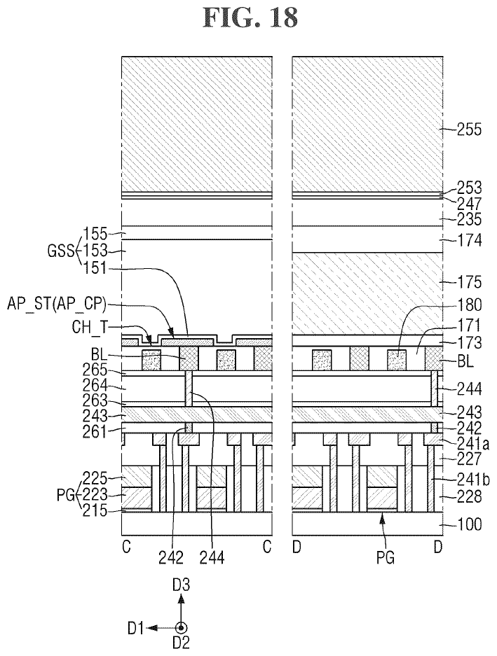

For reference, FIG. 16 is a layout diagram for explaining a semiconductor memory device according to some example embodiments. FIG. 17 is a cross-sectional view taken along A-A and B-B of FIG. 16. FIG. 18 is a cross-sectional view taken along C-C and D-D of FIG. 16.

Referring to FIGS. 16 to 18, the semiconductor memory device according to some example embodiments may further include a shielding structure 180.

The shielding structure 180 may extend in the second direction D2. The shielding structure 180 may be spaced apart from the bit line BL in the first direction D1. The shielding structure 180 may be arranged alternately with the bit line BL in the first direction D1.

The shielding structure 180 may be disposed inside the cell lower insulating film 171. The upper surface of the shielding structure 180 may be lower than the upper surface BL_US of the bit line BL.

The shielding structure 180 may include a conductive material, as an example. As another example, the shielding structure 180 may include a conductive material, and may include an air gap or a void inside the conductive material.

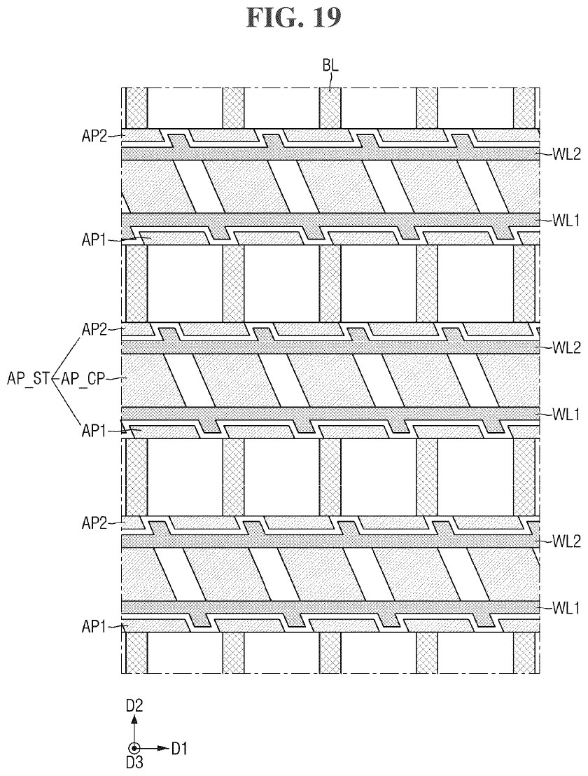

FIGS. 19 to 22 are diagrams for explaining a semiconductor memory device according to some example embodiments. For convenience of explanation, the explanation will focus on points that are different from those explained using FIGS. 1 to 10.

Referring to FIG. 19, in the semiconductor memory device according to some example embodiments, the first channel pattern AP1 and the second channel pattern AP2 may be arranged alternately in a diagonal direction with respect to the first direction D1 and the second direction D2. Here, the diagonal direction may be parallel to the upper surface of the substrate 100.

The channel structure AP_ST may be formed to be twisted in the diagonal direction. From the planar viewpoint, the first channel pattern AP1, the second channel pattern AP2, and the connecting channel pattern AP_CP may each have a parallelogram shape or a rhombic shape. The WLb portions of the word lines may be twisted to match or substantially match the diagonal direction.

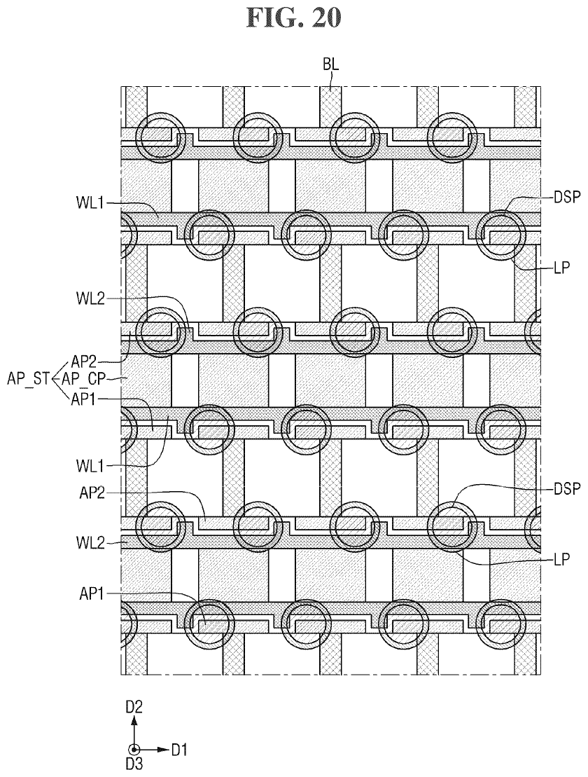

Referring to FIG. 20, in the semiconductor memory device according to some example embodiments, the landing pads LP and the data storage patterns DSP may be arranged in the form of a zigzag or honeycomb from the planar viewpoint.

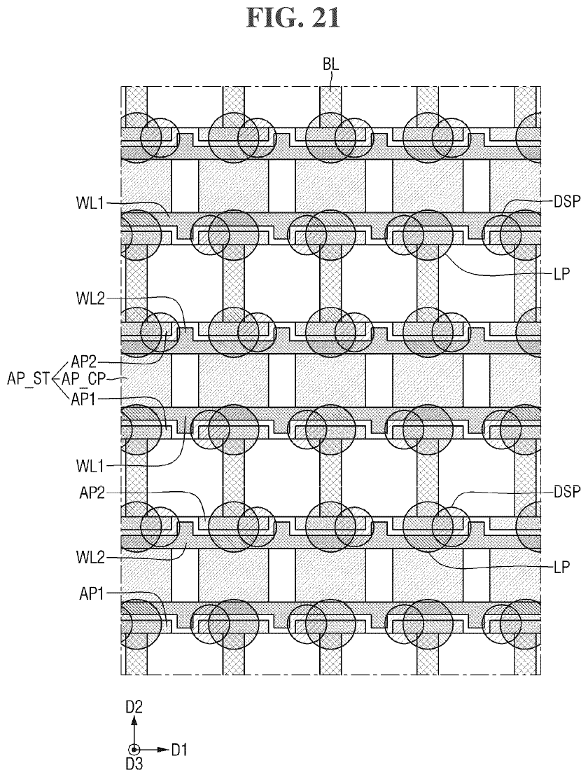

Referring to FIG. 21, in the semiconductor memory device according to some example embodiments, the data storage patterns DSP may be disposed to be dislocated from the landing pads LP from the planar viewpoint.

Each data storage pattern DSP may be in contact with a part of the landing pad LP.

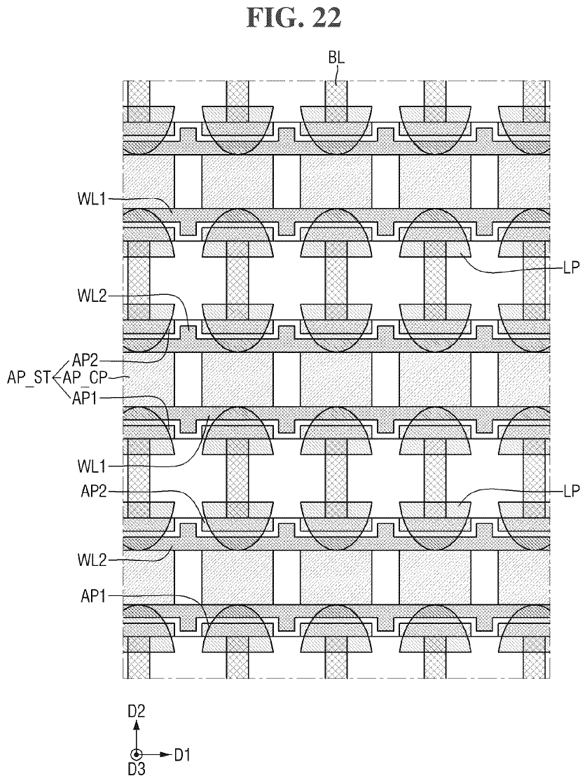

Referring to FIG. 22, in the semiconductor memory device according to some example embodiments, each of the landing pads LP disposed on the first channel pattern AP1 and the second channel pattern AP2 may have a semicircular form or a semi-elliptical form from the planar viewpoint.

From the planar viewpoint, the landing pads LP may be disposed symmetrically with each other.

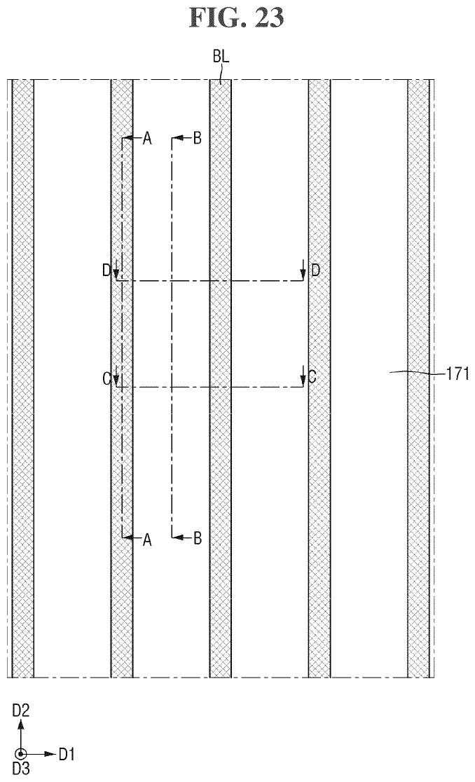

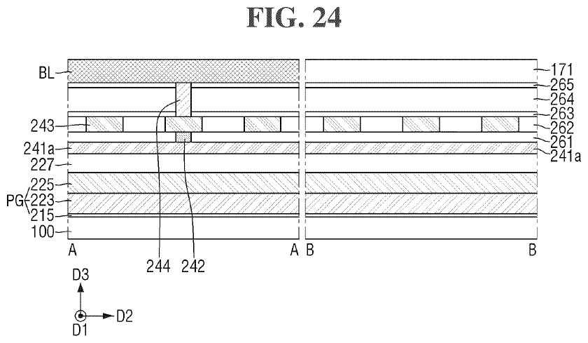

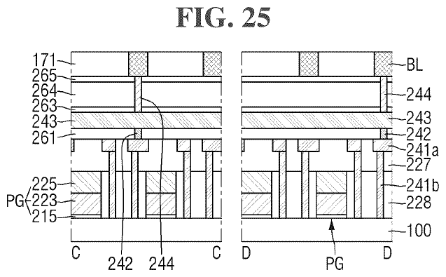

FIGS. 23 to 38 are diagrams for explaining a method for fabricating the semiconductor memory device according to some example embodiments.

Referring to FIGS. 23 to 25, the peri-gate structure PG may be formed on the substrate 100.

A first peri-wiring line 241a and a peri-contact plug 241b may be formed on the substrate 100.

The peri-upper insulating films 261, 262, 263, 264 and 265 may be sequentially formed on the first peri-wiring line 241a and the peri-contact plug 241b. The second peri-wiring line 243, the peri-via plug 242 and the cell connection plug 244 may be formed inside the peri-upper insulating films 261, 262, 263, 264 and 265.

The bit lines BL may then be formed on the fifth peri-upper insulating film 265. The bit line BL may extend long on the substrate 100 in the second direction D2. The cell lower insulating film 171 may be formed on the fifth peri-upper insulating film 265. The cell lower insulating film 171 may expose the upper surface of the bit line BL.

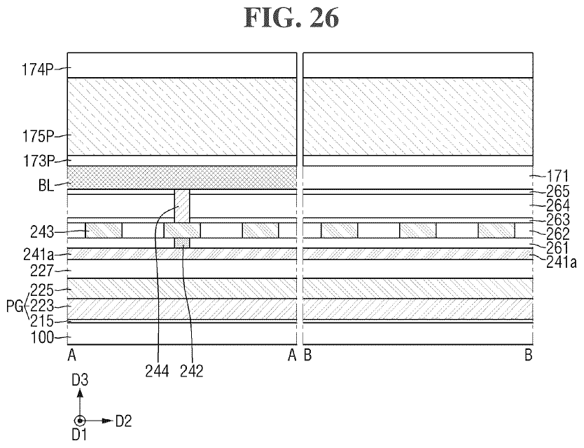

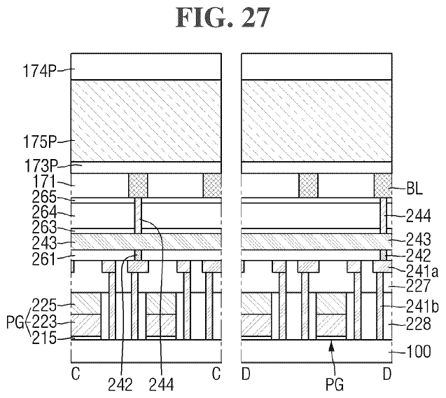

Referring to FIGS. 26 and 27, a pre-etching stop film 173P, a pre-back gate electrode 175P, and a pre-back gate capping film 174P may be formed on the bit line BL and the cell lower insulating film 171.

In some example embodiments, the pre-etching stop film 173P may be formed on the upper surface BL_US of the bit line BL and the upper surface of the cell lower insulating film 171. The pre-etching stop film 173P may include a material having an etch selectivity with the pre-back gate electrode 175P.

The pre-back gate electrode 175P may be formed on the upper surface of the pre-etching stop film 173P. The pre-back gate capping film 174P may be formed on the upper surface of the pre-back gate electrode 175P.

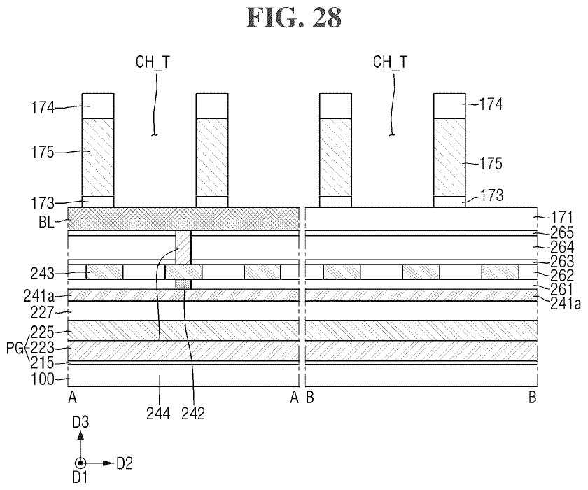

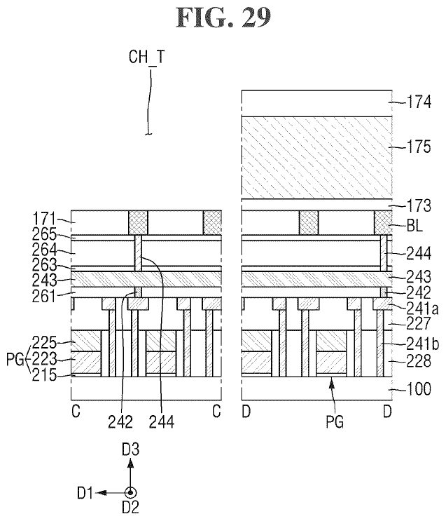

Referring to FIGS. 28 and 29, an etching stop film 173, a back gate electrode 175, and a back gate capping film 174 may be formed on the substrate 100.

In some example embodiments, a mask layer may be formed on the pre-back gate capping film 174P. Subsequently, the pre-back gate capping film 174P may be patterned, using the mask layer. The mask layer and/or the back gate capping film 174P may be used as an etching mask to form the back gate electrode 175 and the etching stop film 173. Each of the etching stop film 173, the back gate electrode 175 and the back gate capping film 174 may extend in the first direction D1.

The etching stop film 173, the back gate electrode 175, and the back gate capping film 174 may include a plurality of channel trenches CH_T extending in the first direction D1. The channel trench CH_T may intersect the bit line BL. The channel trench CH_T may expose the bit line BL.

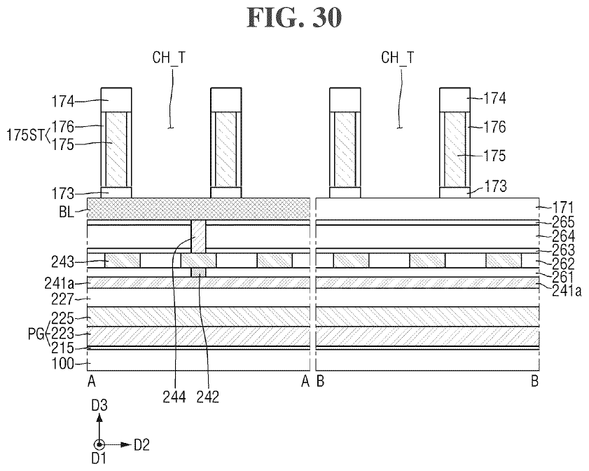

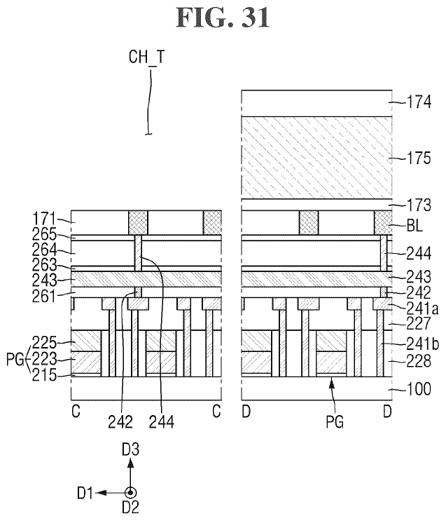

Referring to FIGS. 30 and 31, the back gate structure 175ST may be formed on the etching stop film 173.

In some example embodiments, a back gate insulating film 176 may be formed on side walls of the back gate electrode 175 by an oxidation process. The back gate insulating film 176 may be formed on both side walls of the back gate electrode 175. The thickness of formation of the back gate insulating film 176 may vary depending on the conditions of the oxidation process. The back gate insulating film 176 may not be formed between the etching stop film 173 and the back gate electrode 175.

As the semiconductor memory device becomes smaller, the difficulty of gap fill increases. For example, it may be difficult to deposit a conductive material in a narrow trench. When the back gate insulating film is deposited on the trench and the back gate electrode is deposited, the conductive material may not completely fill the trench. As a result, the reliability of the semiconductor memory device may decrease.

In the semiconductor memory device according to some example embodiments, the back gate electrode 175 is formed by etching the pre-back gate electrode 175P. Subsequently, a back gate insulating film 176 is formed on side walls of the back gate electrode 175, using an oxidation process. Therefore, the back gate structure 175ST may be uniformly formed on one side of the channel structure AP_ST. As a result, reliability of the semiconductor memory device may be improved.

The etching stop film 173, the back gate structure 175ST and the back gate capping film 174 may include a plurality of channel trenches CH_T extending in the first direction D1.

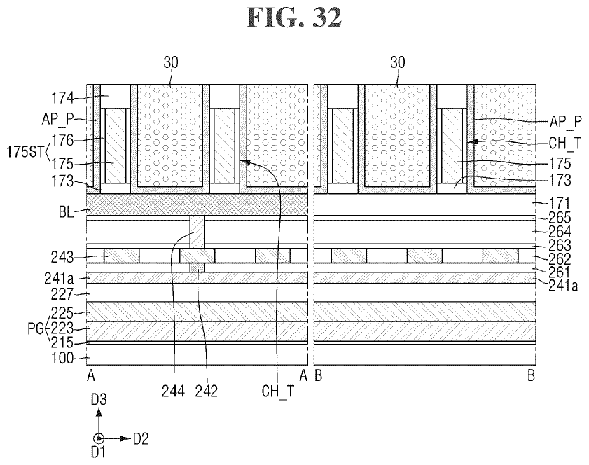

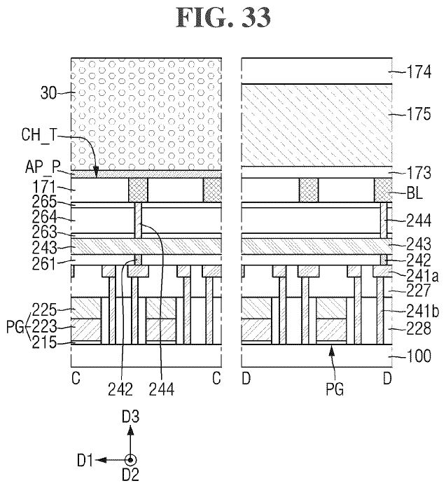

Referring to FIGS. 32 and 33, the pre-channel structure AP_P may be formed along the side walls and lower surface of the channel trench CH_T.

The pre-channel structure AP_P may be in contact with the bit line BL exposed by the channel trench CH_T. The pre-channel structure AP_P is not formed on the upper surface of the back gate capping film 174.

A sacrificial film 30 may then be formed on the pre-channel structure AP_P. The sacrificial film 30 may fill the channel trench CH_T. The sacrificial film 30 may be, but not limited to, one of insulating materials and a silicon oxide film formed, using a SOG (Spin On Glass) technique.

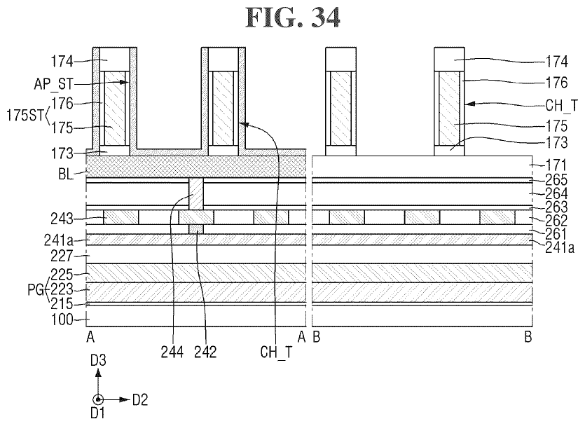

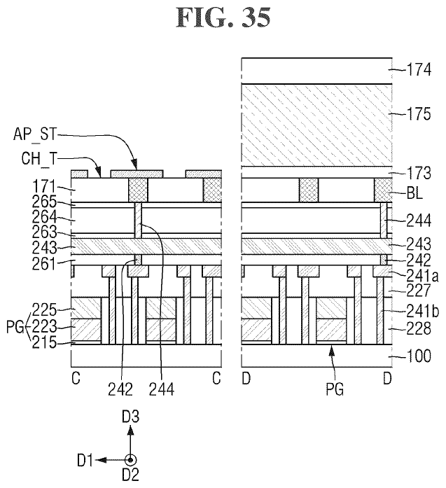

Referring to FIGS. 34 and 35, the pre-channel structure AP_P may be patterned to form a channel structure AP_ST extending along the side walls and lower surface of the channel trench CH_T.

In some example embodiments, a channel separation mask may be formed on the sacrificial layer 30 and the back gate capping film 174. A part of the sacrificial film 30 may be removed, using a channel separation mask. By removing a part of the sacrificial film 30, a part of the pre-channel structure AP_P may be exposed.

A part of the exposed pre-channel structure AP_P may be removed, using an etching process. Accordingly, the channel structure AP_ST may be formed in the channel trench CH_T.

The sacrificial film 30 may then be removed in the channel trench CH_T.

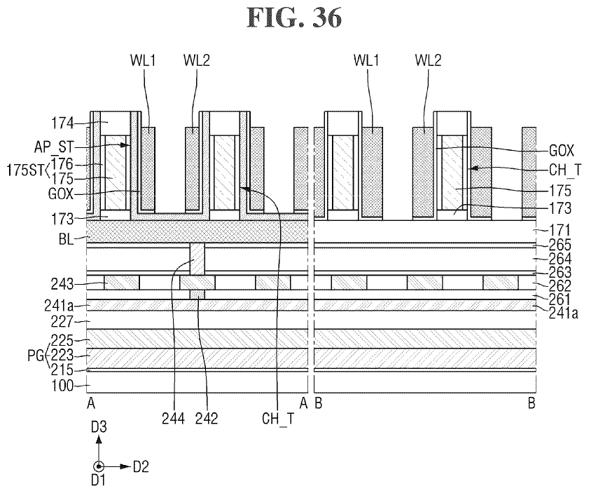

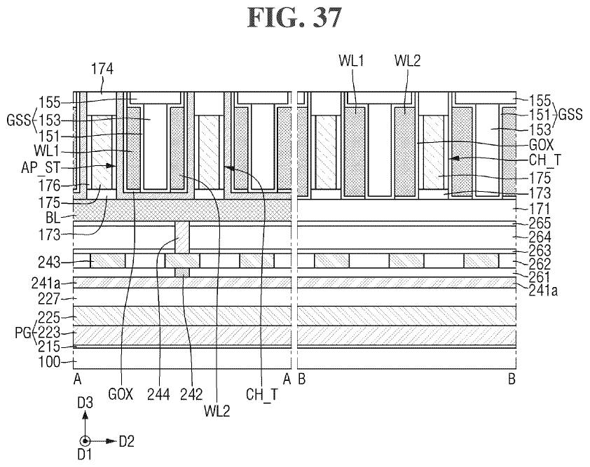

Referring to FIGS. 36 and 37, the gate insulating film GOX may be formed on the channel structure AP_ST.

The gate insulating film GOX may be formed along the profile of the channel structure AP_ST. In a portion in which the channel structure AP_ST is not formed, the gate insulating film GOX may be formed along side walls of the back gate capping film 174 and side walls 175ST_SW of the back gate structure 175ST. The gate insulating film GOX may be formed, but not limited to, using at least one of physical vapor deposition (PVD), thermal chemical vapor deposition (thermal CVD), low pressure chemical vapor deposition (LP-CVD), plasma enhanced chemical vapor deposition (PE-CVD) or atomic layer deposition (ALD) techniques.

Subsequently, a first word line WL1 and a second word line WL2 may be formed on the gate insulating film GOX. The first word line WL1 and the second word line WL2 may be formed along side walls of the channel trench CH_T.

Formation of the first word line WL1 and the second word line WL2 may include performance of an anisotropic etching process on the gate conductive film after depositing a gate conductive film on the gate insulating film GOX.

At the time of the anisotropic etching process on the gate conductive film, a part of the gate insulating film GOX may be etched. Accordingly, the gate insulating film GOX between the first word line WL1 and the channel structure AP_ST may be separated from the gate insulating film GOX between the second word line WL2 and the channel structure AP_ST. Unlike the shown example, the gate insulating film GOX may be used as an etching stop film at the time of the anisotropic etching process on the gate conductive film.

The upper surface of the first word line WL1 and the upper surface of the second word line WL2 may be positioned at a level lower than the upper surface 174_US of the back gate capping film 174.

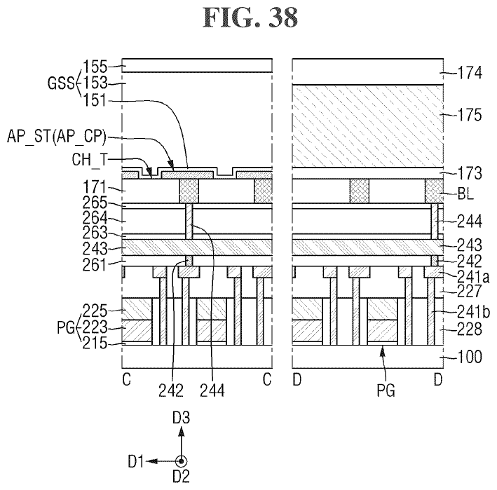

Referring to FIGS. 37 and 38, the gate separation pattern GSS may be formed on the first word line WL1 and the second word line WL2. The gate separation pattern GSS may fill the channel trench CH_T.

In some example embodiments, the gate separation liner 151 may be formed along the profile of the first word line WL1 and the profile of the second word line WL2. The gate separation liner 151 may also be formed on the upper surface 174_US of the back gate capping film 174.

A pre-filling film may be formed on the gate separation liner 151. The pre-filling film may also be formed on the upper surface 174_US of the back gate capping film 174. The gate separation filling film 153 may be formed on the gate separation liner 151, by removing a part of the pre-filling film.

A pre-capping film may be formed on the gate separation filling film 153. The pre-capping film may also be formed on the upper surface 174_US of the back gate capping film 174. The gate separation capping film 155 may be formed by removing a part of the pre-capping film. While forming the gate separation capping film 155, the gate separation liner 151 and the pre-capping film formed on the upper surface 174_US of the back gate capping film 174 may be removed.

A voltage may be applied to the back gate electrode 175 in the semiconductor device according to some example embodiments. The voltage applied to the back gate electrode 175 may change a threshold voltage (Vth) of the first word line WL1 and the second word line WL2. That is, the threshold voltage (Vth) of the semiconductor memory device may be adjusted, by adjusting the voltage applied to the back gate electrode 175.

Oxygen of the channel structure AP_ST may partially disappear in the manufacturing process of the semiconductor memory device. For example, in the heat treatment process, oxygen of the channel structure AP_ST disappears, and the composition ratio of oxygen in the channel structure AP_ST may be reduced. In the semiconductor device according to some example embodiments, the back gate insulating film 176 may be in contact with the channel structure AP_ST. The back gate insulating film 176 may provide oxygen to the channel structure AP_ST. As a result, the channel structure AP_ST may compensate for oxygen lost in the manufacturing process.

Referring to FIGS. 2 and 3, the uppermost face of the channel structure AP_ST may become lower than the upper surface 174_US of the back gate capping film 174, by removing a part of the channel structure AP_ST. A pre-landing pad film may then be formed on the back gate capping film 174, the gate separation pattern GSS and the channel structure AP_ST. The pre-landing pad film may be patterned to form the landing pad LP on the channel structure AP_ST.

A data storage pattern DSP may then be formed on the landing pad LP. The data storage pattern DSP may be connected to the channel structure AP_ST and formed on the gate separation pattern GSS.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

In concluding the detailed description, those skilled in the art will appreciate that many variations and modifications may be made to the preferred embodiments without substantially departing from the principles of the present inventive concept. Therefore, the disclosed example embodiments of the inventions are used in a generic and descriptive sense only and not for purposes of limitation.

What is claimed is:

1. A semiconductor memory device comprising:
a bit line extending in a first direction on a substrate;
a channel structure on the bit line, the channel structure including a first vertical part extending in a second direction, and a second vertical part spaced apart from the first vertical part in the first direction and extending in the second direction;
a back gate electrode on the bit line on at least one side of the channel structure and extending in the second direction;
a back gate insulating film between the back gate electrode and the channel structure;
a back gate capping film on the back gate electrode and the back gate insulating film;
a first word line between the first vertical part and the second vertical part and extending in the second direction;
a second word line between the first vertical part and the second vertical part, extending in the second direction, and spaced apart from the first word line in the first direction; and
a first capacitor and a second capacitor connected to the first vertical part and the second vertical part, on the first vertical part and the second vertical part.

2. The semiconductor memory device of claim 1,
wherein a height up to an upper surface of the gate electrode is equal to or smaller than a height up to an upper surface of the first vertical part, measured from an upper surface of the bit line.

3. The semiconductor memory device of claim 2,
wherein the height up to the upper surface of the gate electrode is smaller than the height up to an upper surface of the first word line, measured from the upper surface of the bit line.

4. The semiconductor memory device of claim 1, further comprising:
an etching stop film between the bit line and the gate electrode.

5. The semiconductor memory device of claim 4,
wherein a lower surface of the back gate electrode is in contact with the etching stop film.

6. The semiconductor memory device of claim 4, wherein
the channel structure includes a horizontal part connecting the first vertical part and the second vertical part, and
a thickness of the horizontal part is smaller than a thickness of the etching stop film in the second direction.

7. The semiconductor memory device of claim 1,
wherein a height up to an upper surface of the first word line is different from a height up to an upper surface of the first vertical part measured from an upper surface of the bit line.

8. The semiconductor memory device of claim 1,
wherein a part of the first vertical part overlaps the back gate capping film in the first direction.

9. The semiconductor memory device of claim 1, further comprising:
a gate insulating film between the first word line and the channel structure.

10. The semiconductor memory device of claim 1, further comprising:
a gate separation pattern on the bit line, and separating the first word line and the second word line,
wherein the channel structure includes a horizontal part connecting the first vertical part and the second vertical part, and
the gate separation pattern is in contact with the horizontal part of the channel structure.

11. The semiconductor memory device of claim 1, further comprising:
a gate separation pattern on the bit line, and separating the first word line and the second word line,
wherein a height up to an upper surface of the back gate capping film is equal to a height up to an upper surface of the gate separation pattern, measured from an upper surface of the bit line.

12. A semiconductor memory device comprising:
a bit line extending in a first direction on a substrate;
a back gate structure defining a channel trench exposing the bit line and extending in a second direction intersecting the first direction, on the substrate;
an etching stop film between the back gate structure and the bit line;
a channel structure extending along a lower surface and side faces of the channel trench, and including a first channel pattern, and a second channel pattern spaced apart from the first channel pattern in the first direction;
a first word line and a second word line spaced apart from each other in the first direction on the channel structure, and each extending in the second direction; and
a gate insulating film between the first channel pattern and the first word line, and between the second channel pattern and the second word line; and
a first capacitor and a second capacitor connected to the first channel pattern and the second channel pattern, on the first channel pattern and the second channel pattern,
the back gate structure including a back gate electrode, and a back gate insulating film between the back gate electrode and the channel structure, and
a height up to an upper surface of the back gate structure being equal to or smaller than a height up to an upper surface of the first word line, measured from an upper surface of the bit line.

13. The semiconductor memory device of claim 12, further comprising:
a back gate capping film on the upper surface of the back gate structure.

14. The semiconductor memory device of claim 12,
wherein the back gate electrode is in contact with the etching stop film.

15. The semiconductor memory device of claim 12,
wherein the gate electrode includes at least one of polysilicon and a conductive metal.

16. The semiconductor memory device of claim 12, further comprising:
a gate separation pattern on the bit line, and separating the first word line and the second word line,
wherein the gate separation pattern is in contact with the bit line.

17. The semiconductor memory device of claim 12,
wherein the channel structure includes an IGZO.

18. The semiconductor memory device of claim 12, further comprising:
a shielding structure extending in the first direction, and is spaced apart from the bit line in the second direction.

19. The semiconductor memory device of claim 12,
wherein the height up to the upper surface of the first word line is equal to or greater than a height up to the upper surface of the first channel pattern, measured from the upper surface of the bit line.

20. A semiconductor memory device comprising:
a bit line extending in a first direction on a substrate;
a channel structure on the bit line, and including a first vertical part extending in a second direction, and a second vertical part spaced apart from the first vertical part in the first direction and extending in the second direction;
a back gate electrode on the bit line on at least one side of the channel structure, and including a back gate electrode extending in the second direction, and a back gate insulating film between the back gate electrode and the channel structure;
an etching stop film between the bit line and the back gate structure;
a back gate insulating film between the back gate electrode and the channel structure;
a back gate capping film on the back gate electrode and the back gate insulating film;
a first word line between the first vertical part and the second vertical part and extending in the second direction;
a second word line between the first vertical part and the second vertical part, extending in the second direction, and spaced apart from the first word line in the first direction;
a gate insulating film between the first vertical part and the first word line, and between the second vertical part and the second word line; and
a first capacitor and a second capacitor connected to the first vertical part and the second vertical part, on the first vertical part and the second vertical part,
a height up to an upper surface of the back gate structure being equal to or smaller than a height up to an upper surface of the first word line, measured from an upper surface of the bit line.
